(19) United States
(12) Patent Application Publication
(10) Pub. No.: US 2009/0185120 A1
(43) Pub. Date: Jul. 23, 2009

(54) THIN FILM TRANSISTOR SUBSTRATE AND METHOD FOR MANUFACTURING THE SAME

(75) Inventors: Soo-Wan YOON, Suwon-si (KR); Ho-Yun BYUN, Hwaseong-si (KR); Jeong-Uk HEO, Seongnam-si (KR); Chong-Chul CHAI, Seoul (KR); Nam-Seok LEE, Suwon-si (KR); Su-Jeong KIM, Seoul (KR); Sung-Hwan HONG, Suwon-si (KR); Seong-Nam LEE, Seoul (KR); Jung-Hun LEE, Seoul (KR); Ji-Yoon JUNG, Cheonan-si (KR); Kwang-Hyun KIM, Guri-si (KR); Kyong-Ok PARK, Bucheon-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/352,143

(22) Filed: Jan. 12, 2009

(30) Foreign Application Priority Data
Jan. 18, 2008 (KR) 10-2008-0005647

(51) Int. Cl. G02F 1/1333; H01L 27/088; H01L 31/042; H01L 21/77; H01L 31/18

(52) U.S. Cl. 349/116; 257/59; 257/40; 438/73; 438/29; 257/E21.535; 257/E27.06; 257/E51.001; 257/E31.001

(57) ABSTRACT

A thin-film transistor (“TFT”) substrate includes; a substrate including both a light-transmitting region and a light-blocking region, a solar cell pattern disposed on the light-blocking region of the substrate, and comprising at least one solar cell, an insulation layer disposed on the solar cell pattern, and a TFT disposed on the insulation layer.

This application claims priority to Korean Patent Application No. 10-2008-0005647, filed on Jan. 18, 2008, and all the benefits accruing therefrom under 35 U.S.C. §119, the contents of which in its entirety are herein incorporated by reference.

### BACKGROUND OF THE INVENTION

The present disclosure relates to a thin film transistor (“TFT”) substrate and a method for manufacturing the same, and more particularly, to a TFT substrate having a solar cell and a method for manufacturing the TFT substrate.

A liquid crystal display (“LCD”), which is one of a variety of different types of display devices, displays an image by controlling transmittance of light emitted from a light source using the optical anisotropy of liquid crystal molecules and the polarization property of a polarizer. One advantage of an LCD is that it can be made to be relatively lightweight and may also have a slim profile and a high resolution even in a large size display. Also, since a typical LCD has low power consumption, its areas of application have rapidly expanded.

A typical LCD includes a color filter substrate where a black matrix, a color filter and a common electrode, and various other components, are formed, a TFT substrate where a TFT, a pixel electrode, and various other components, are formed, and a liquid crystal layer filled between the color filter substrate and the TFT substrate. An electric field formed between the common electrode and the pixel electrode controls the orientation of liquid crystal molecules to change light transmittance through the liquid crystal layer, so that the LCD displays a desired image. Furthermore, since the liquid crystal layer cannot emit light by itself, a backlight unit, which provides light allowing the displayed image or the like to be visualized, is necessarily disposed under a display panel of the LCD.

In a typical LCD, power is largely consumed in a backlight unit. Therefore, in an environment of requiring low power consumption, for example, an LCD for a mobile apparatus, the reduction of power consumed in the backlight unit becomes a more critical issue. To reduce power consumption, a related art method of reducing power consumption has been used, where the brightness of the backlight unit is actively controlled according to peripheral brightness so as to reduce power consumption. However, this related art method still has such a limitation that: an image quality is deteriorated if the brightness is decreased; and the resultant power savings are minimal. Therefore, studies are recently being conducted on a power-reducing method, in which a solar cell is formed on an LCD panel to convert external light into an electrical energy, which may then be used as a power supply for operating the LCD panel or a backlight unit. To form the solar cell on the LCD panel, the solar cell may be separately prepared and then attached to the LCD panel, or the solar cell may be directly formed on the LCD panel.

However, in the method where the solar cell is separately prepared and then attached to the LCD panel, it is difficult to secure a space to attach the solar cell and further it is necessary to perform manufacturing and mounting processes of the solar cell. Also, in the method where the solar cell is directly formed on the LCD panel, a mask process should be additionally performed to form the solar cell. Therefore, both the methods of disposing the solar cell on the LCD panel lead to an unwanted increase in manufacturing time and manufacturing cost.

### BRIEF SUMMARY OF THE INVENTION

The present disclosure provides an exemplary embodiment of a thin film transistor (“TFT”) substrate, in which a solar cell can be formed without an additional mask process by forming the solar cell through a mask process of forming a gate pattern, and an exemplary embodiment of a method for manufacturing the solar cell.

The present disclosure also provides an exemplary embodiment of a TFT substrate, in which a color filter can be easily formed on the TFT substrate through a liquid inkjet method by providing a solar cell serving as a partition dividing a space into a light-transmitting region and a light-blocking region and thus preventing a liquid color filter formed in the light-transmitting region from flowing into an adjacent region, and an exemplary embodiment of a method for manufacturing the TFT substrate.

The present disclosure also provides an exemplary embodiment of a TFT substrate capable of reducing power consumption by reusing energy of light incident on a light-blocking region, which does not contribute to an image display, and an exemplary embodiment of a method for manufacturing the TFT substrate.

In accordance with one exemplary embodiment, a TFT substrate includes; a substrate including both a light-transmitting region and a light-blocking region, a solar cell pattern disposed on the light-blocking region of the substrate, and having at least one solar cell, an insulation layer disposed on the solar cell pattern, and a TFT disposed on the insulation layer.

In one exemplary embodiment, the TFT substrate may further include a plurality of electrode pads extending from the solar cell pattern to an outer edge of the substrate.

In one exemplary embodiment, the solar cell may include; a first electrode layer disposed on the substrate; an active layer disposed on the first electrode layer, and a second electrode layer disposed on the active layer.

In one exemplary embodiment, the first electrode layer may be formed of a transparent conductive material, and the second electrode layer may be formed of the same material as a gate electrode of the TFT.

In one exemplary embodiment, the transparent conductive material may include one of indium tin oxide (ITO) and indium zinc oxide (IZO).

In one exemplary embodiment, the gate electrode may include at least one of aluminum (Al), molybdenum (Mo), chromium (Cr), titanium (Ti), tantalum (Ta), silver (Ag) and neodymium (Nd).

In one exemplary embodiment, the solar cell may include at least one of a dye-sensitized solar cell, an inorganic semiconductor solar cell and an organic semiconductor solar cell.

In one exemplary embodiment, the solar cell pattern may have a predetermined height and surround the light-transmitting region, and a color filter may be provided in the region surrounded by the solar cell pattern.

In accordance with another exemplary embodiment, a method for manufacturing a TFT substrate includes; preparing a substrate including a light-transmitting region and a light-blocking region, disposing a first electrode layer, an active layer and a second electrode layer on the substrate in sequence to form a solar cell layer; disposing an insulation layer on the solar cell layer, disposing a gate line layer on the insulation layer, and patterning the gate line layer, the insulation layer and the solar cell layer to form a solar cell pattern in at least a portion of the light-blocking region from the solar cell layer, and to form a gate pattern including a gate electrode and a gate line from the gate line layer.

In one exemplary embodiment, the first electrode layer may be formed of a transparent conductive material.

In one exemplary embodiment, the transparent conductive material may include one of indium tin oxide (ITO) and indium zinc oxide (IZO).

In one exemplary embodiment, the second electrode layer may be formed of the same material as the gate line layer.

In one exemplary embodiment, the gate line layer may include at least one of aluminum (Al), molybdenum (Mo), chromium (Cr), titanium (Ti), tantalum (Ta), silver (Ag) and neodymium (Nd).

In one exemplary embodiment, the patterning of the gate line layer, the insulation layer and the solar cell layer may further include simultaneously forming a first electrode pad and a second electrode pad from the solar cell layer. Herein, the first electrode pad may be connected to the first electrode layer of the solar cell pattern, and the second electrode pad may be connected to the second electrode layer of the solar cell pattern.

In one exemplary embodiment, the patterning of the gate line layer, the insulation layer and the solar cell layer may include; forming a first photoresist pattern with first, second and third thicknesses on the gate line layer and etching an underlying layer using the first photoresist pattern as an etch mask, to define a first region where a gate pattern, a solar cell pattern and a plurality of electrode pads are to be formed, forming a second photoresist pattern by removing a portion of the first photoresist pattern substantially equal to the third thickness and etching an underlying layer of the first region using the second photoresist pattern as an etch mask, to remove an overlying layer of the first electrode pad, and forming a third photoresist pattern by removing a portion of the second photoresist pattern substantially equal to the second thickness and etching an underlying layer of the first region using the third photoresist pattern as an etch mask, to form a gate pattern.

In one exemplary embodiment, the first thickness may be greater than the second thickness, and the second thickness may be greater than the third thickness.

In one exemplary embodiment, the method may further include forming a color filter in an inner space surrounded by the solar cell pattern after the patterning of the gate line layer, the insulation layer and the solar cell layer.

In one exemplary embodiment, the color filter may be formed through an inkjet method.

### BRIEF DESCRIPTION OF THE DRAWINGS

Exemplary embodiments can be understood in more detail from the following description taken in conjunction with the accompanying drawings, in which:

FIG. 1A is a top plan view of an exemplary embodiment of a thin film transistor (“TFT”) substrate in accordance with the present invention;

FIG. 1B is a magnified top plan view of an exemplary embodiment of a pixel of the TFT substrate of FIG. 1A;

FIG. 2 is a cross-sectional view taken along lines I-II, II-III and III-IV of FIGS. 1A and 1B;

FIGS. 3 through 9 are cross-sectional views illustrating an exemplary embodiment of a method for manufacturing the exemplary embodiment of a TFT substrate of FIGS. 1 and 2 in accordance with the present invention;

FIG. 10 is a cross-sectional view of another exemplary embodiment of a TFT substrate taken along lines I-II, II-III and III-IV of FIGS. 1A and 1B in accordance with the present invention;

FIGS. 11 through 15 are cross-sectional views illustrating an exemplary embodiment of a method for manufacturing the exemplary embodiment of a TFT substrate of FIG. 10 in accordance with the present invention; and

FIG. 16 is a perspective view of an exemplary embodiment of a liquid crystal display in accordance with the present invention.

### DETAILED DESCRIPTION OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the present invention will be described in detail with reference to the accompanying drawings.

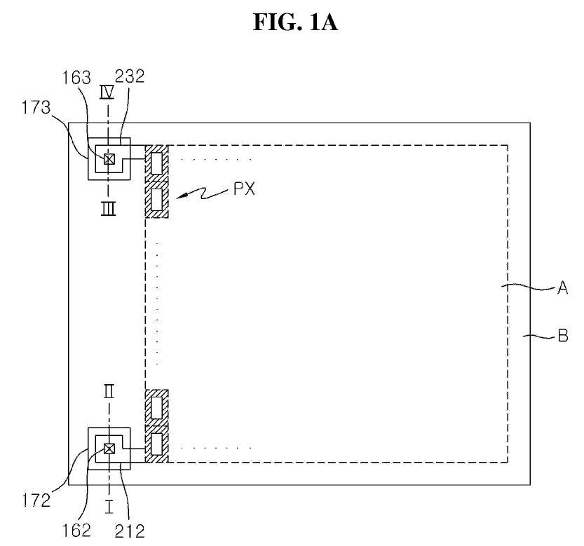

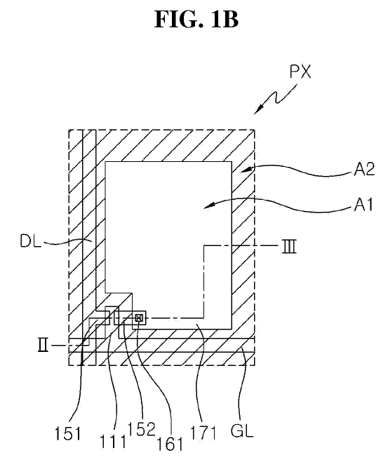

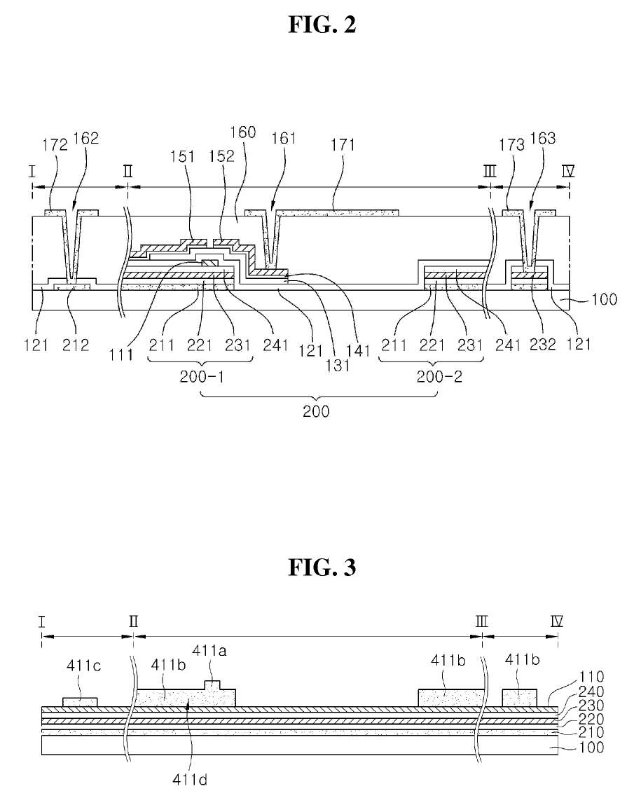

FIG. 1A is a top plan view of an exemplary embodiment of a thin film transistor (“TFT”) substrate including in accordance with the present invention. FIG. 1B is a magnified top plan view of an exemplary embodiment of a pixel of the TFT substrate of FIG. 1A. FIG. 2 is a cross-sectional view taken along lines I-II, II-III and III-IV of FIGS. 1A and 1B.

### Embodiment 1

Referring to FIGS. 1A, 1B and 2, the exemplary embodiment of a TFT substrate is divided into a display region A for displaying an image, and a peripheral region B provided outside the display region A. As shown in FIG. 1B, the display region A may be subdivided into a light-transmitting region A1 for transmitting light so as to display an image, and a light-blocking region A2 for blocking light to separate pixels from each other. In the present exemplary embodiment, a solar cell pattern 200 may be provided in an entire or a partial region of the light-blocking region A2. In the peripheral region B, first and second electrode pads 212 and 232 are formed, which extend from the solar cell pattern 200.

The TFT substrate includes a transparent insulation substrate 100, a gate line GL extending in one direction over the substrate 100, and a data line DL provided over the substrate 100 and extending in another direction substantially perpendicular to the gate line GL. Unit pixels PX are respectively defined in intersection regions where the gate lines GL and the data lines cross each other or regions including the intersection regions and areas adjacent thereto. In each of the unit pixels PX, a TFT and a pixel electrode 171 are provided. In another exemplary embodiment, a storage electrode (not shown) may be further provided in the unit pixel PX. The TFT includes a gate electrode 111, a gate insulation layer 121, an active layer 131, an ohmic contact layer 141, a source electrode 151 and a drain electrode 152. In the present exemplary embodiment, the gate electrode 111 is connected to the gate line GL, the source electrode 151 is connected to the data line DL, and the drain electrode 152 is connected to the pixel electrode 171 through a first contact hole 161. Therefore, when a predetermined gate signal transferred through the gate line GL is applied to the gate electrode 111, a conduction channel is formed in the active layer 131 so that a predetermined data signal transferred through the data line DL can be applied to the pixel electrode 171.

In exemplary embodiments where present, the storage electrode (not shown) forms a storage capacitor together with the pixel electrode 171, which is disposed thereover. The storage electrode (not shown) may be connected to a storage line (not shown) extending substantially parallel with the gate line GL, and thus receives a reference voltage. Accordingly, the data signal charged in the pixel electrode 171 through the storage capacitor can be stably maintained until a following data signal is charged.

The gate insulation layer 121, e.g., a gate dielectric layer, is disposed between the gate line GL and the data line DL, and a passivation layer 160 is disposed between the data line DL and the pixel electrode 171.

A solar cell pattern 200 is provided in an entire or partial portion of the light-blocking region A2. In the present exemplary embodiment, the solar cell pattern 200 is disposed under the gate pattern including the gate electrode 111 and the gate line GL. The solar cell pattern 200 includes at least one of solar cells 200-1 and 200-2 for converting light incident onto a rear side of the TFT substrate into an electrical energy. Here, the solar cells 200-1 and 200-2 may be implemented in various forms. In one exemplary embodiment, the solar cells 200-1 and 200-2 may include one of a dye-sensitized solar cell, an inorganic semiconductor solar cell, an organic semiconductor solar cell or other similar solar cells as would be known to one of ordinary skill in the art. Each of the solar cells 200-1 and 200-2 includes a first electrode 211 disposed on the substrate 100, an active layer 221 disposed on the first electrode 211, and a second electrode 231 on the active layer 221.

In the present exemplary embodiment, the active layer 221 includes a charge transport layer, an n-type layer, a p-type layer and a hole transport layer, which are stacked over the first electrode 211, although alternative exemplary embodiments include configurations wherein the active layer 221 includes additional or fewer layers arranged in different configurations as would be known to one of ordinary skill in the art. In one exemplary embodiment, the first electrode 211 and the first electrode pad 212 connected thereto maybe formed of indium tin oxide (“ITO”) or indium zinc oxide (“IZO”). Accordingly, most of light incident onto the rear side of the light-blocking region A2 can be incident onto the active layers 221 of the solar cells 200-1 and 200-2 in its entirety, and thus used for generating power.

The second electrode 231 and the second electrode pad 232 connected thereto may be formed of substantially the same material as the gate electrode 111. In one exemplary embodiment the second electrode 231 and the electrode pad 232 may be formed from at least one metal of aluminum (Al), molybdenum (Mo), chromium (Cr), titanium (Ti), tantalum (Ta), silver (Ag) and neodymium (Nd). Such metals have lower work function than other metals, making it possible to generate power even when the quantity of light incident upon the active layer 221 is small. In this way, since the solar cells 200-1 and 200-2 are disposed under the gate pattern configured with the gate electrode 111 and the gate line GL, and the second electrode 231 and the second electrode pad 232 connected thereto are formed of the same material as the gate pattern, it is possible to form the solar cells 200-1 and 200-2 together with the gate pattern using the same mask process.

An exemplary embodiment of a method for manufacturing the exemplary embodiment of a TFT substrate of FIGS. 1 and 2 in accordance with the present invention will be described below. In the exemplary embodiment described below, the gate pattern is formed of the same material as the gate line GL, and includes all the patterns which may be formed in the same process, for example, the gate electrode 211, the gate line GL, the storage electrode (not shown), the storage line (not shown), and so forth. Likewise, the data pattern is formed of the same material as the data line DL, and includes all the patterns which may be formed in the same process, for example, the source electrode 151, the drain electrode 151, the data line DL, and so forth.

FIGS. 3 through 9 are cross-sectional views illustrating an exemplary embodiment of a method for manufacturing the exemplary embodiment of a TFT substrate of FIGS. 1 and 2 in accordance with the present invention.

Referring to FIGS. 2 and 3, a transparent insulation substrate 100, exemplary embodiments of which include a glass substrate and a quartz substrate, is prepared first. Thereafter, a first electrode layer 210, an active layer layer 220 and a second electrode layer 230 are sequentially formed on the substrate 100, thereby forming a solar cell layer. A first insulation layer 240 and a gate line layer 110 are formed on the solar cell layer in sequence. Afterwards, a photoresist layer is formed on the gate line layer 110, and exposure and development processes are then performed to form first photoresist patterns 411a, 411b and 411c. In one exemplary embodiment, the first electrode layer 210 may be formed of a transparent conductive material, exemplary embodiments of which include ITO or IZO. The second electrode layer 230 and the gate line layer 110 may be formed of the same material as a gate pattern to be formed later; exemplary embodiments of which include at least one of Al, Mo, Cr, Ti, Ta, Ag and Nd.

In the exposure and development process to form the first photoresist patterns, the first photoresist patterns 411a, 411b and 411c are formed to have different thicknesses by the use of a slit mask or a half tone mask that allows respective exposure areas to be differently exposed. Specifically, the first photoresist pattern 411a is formed to a first thickness over a region where the gate pattern, e.g., the gate electrode 111 and the gate line GL, will be formed, the first photoresist pattern 411b is formed to a second thickness over a region where the solar cell pattern 200 and the second electrode pad 232 will be formed, the first photoresist pattern 411c is formed to a third thickness over a region where the first electrode pad 212 will be formed, and the other portions of the photoresist layer are removed. Because the first photoresist pattern 411a is formed to the first thickness over the region where the gate pattern 111 and GL will be formed and the first photoresist pattern 411b is formed to the second thickness over the region where only the solar cell pattern 200 will be formed, a portion of the first photoresist pattern 411a has a stepped structure. Herein, the first thickness is greater than the second thickness, and the second thickness is greater than the third thickness.

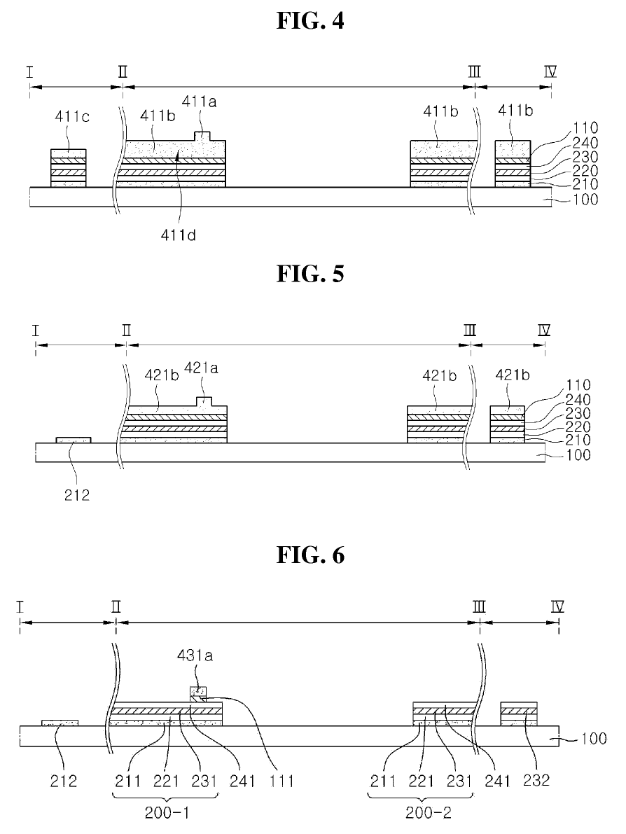

Referring to FIGS. 2 and 4, all of the underlying layers, i.e., the gate line layer 110, the first insulation layer 240, the second electrode layer 230, the active layer layer 220 and the first electrode layer 210, are etched using the first photoresist patterns 411a, 411b and 411c as an etch mask, thereby defining a first region where the gate pattern 111 and GL, the solar cell pattern 200 and the first and second electrode pads 212 and 213 will be formed. In one exemplary embodiment, a region for forming the solar cell pattern 200 may be only a portion of a light-blocking region A2. In another exemplary embodiment, a region for forming the solar cell pattern 200 may be the whole area of the light-blocking region A2 and a portion of the peripheral region B. The solar cell pattern 200 in the present exemplary embodiment is formed in only a portion of the light-blocking region A2 of the display region A.

Referring to FIGS. 2 and 5, the first photoresist patterns 411a, 411b and 411c are ashed by a predetermined thickness, e.g., the third thickness, to thereby form second photoresist patterns 421a and 421b, having thicknesses smaller than the first photoresist patterns 411a and 411b, respectively. Thereafter, the underlying layers of the first region, that is, the gate line layer 110, the first insulation layer 240, the second electrode 230, the active layer 220 and the first electrode layer 210 are etched using the second photoresist patterns 421a and 421b as an etch mask, so that the layers overlying the first electrode pad 212 are removed. Meanwhile, the second photoresist patterns 421a and 421b may remain only on the region where the gate pattern 111 and GL, the solar cell pattern 200 and the second electrode pad 232 will be formed.

Referring to FIGS. 2 and 6, the second photoresist patterns 421a and 421b are ashed again by a predetermined thickness, e.g., the second thickness, thereby forming a third photoresist pattern 431a, having a thickness smaller than the second photoresist pattern 421a. That is, the second photoresist pattern 421b may be removed, and the thickness of the second photoresist pattern 421 a may be decreased to form the third photoresist pattern 431a. Subsequently, the gate line layer 110 in the first region is etched using the third photoresist pattern 431a as an etch mask to form the gate electrode 111 having a narrow line width. This etching also removes the rest of the gate line layer 110 existing over the solar cell pattern 200-1 and 200-2 and the second electrode pad 232. During this process, the first electrode pad 212 may remain since the first electrode pad 212 has an etch rate that is very smaller than an etch rate of the gate line layer 110 with regard to this etching. Thereafter, the third photoresist pattern 431a is ashed.

Referring to FIGS. 2 and 7, the gate insulation layer 121 is formed on an entire structure including the gate electrode 111. The active layer 131 and the ohmic contact layer 141 are sequentially formed on the second insulation layer 121 to form a multi-structured semiconductor layer, and then patterned to form an isolated and island-shaped semiconductor layer over the gate electrode 111. In one exemplary embodiment, the gate insulation layer 121 may be formed of an inorganic insulation material including at least one of silicon oxide (SiO₂) and silicon nitride (SiNx) having excellent adhesive and insulating properties. In one exemplary embodiment, the active layer 131 may be formed of amorphous silicon (“a-Si”). In one exemplary embodiment, the ohmic contact layer 141 may be formed of silicide or n-type heavily doped amorphous silicon (“n+ a-Si”). Furthermore, alternative exemplary embodiments include configurations wherein each unit pixel PX includes a plurality of island-shaped semiconductor layers.

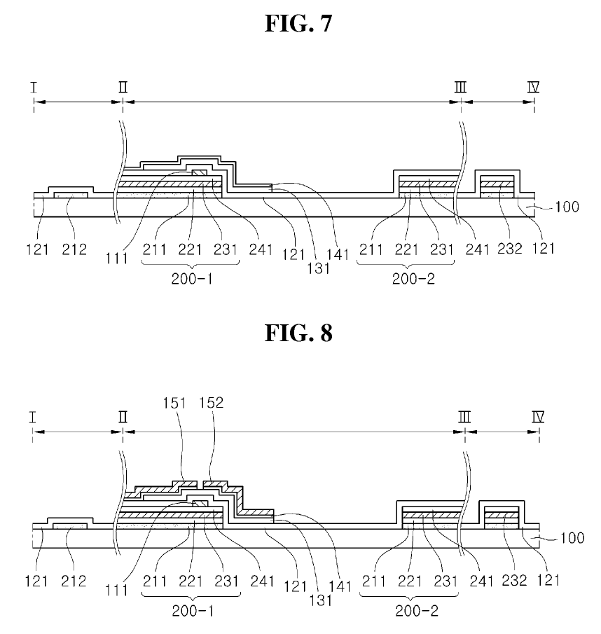

Referring to FIGS. 2 and 8, a data line layer (not shown) is formed on an entire structure including the island-shaped semiconductor layer, and then patterned to form a data pattern including the source electrode 151, the drain electrode 152 and the data line (see DL of FIG. 1). In one exemplary embodiment, the data line layer may be formed of at least one of Al, Mo, Cr, Ti, Ta, Ag and Nd. Afterwards, the ohmic contact layer 141 exposed between the source electrode 151 and the drain electrode 152 is removed so that at least one TFT, which includes the gate electrode 111, the gate insulation layer 121, the active layer 131, the ohmic contact layer 131, the source electrode 151 and the drain electrode 152, is provided in each unit pixel PX. Such a TFT serves as a switching component capable of independently operating a unit pixel PX.

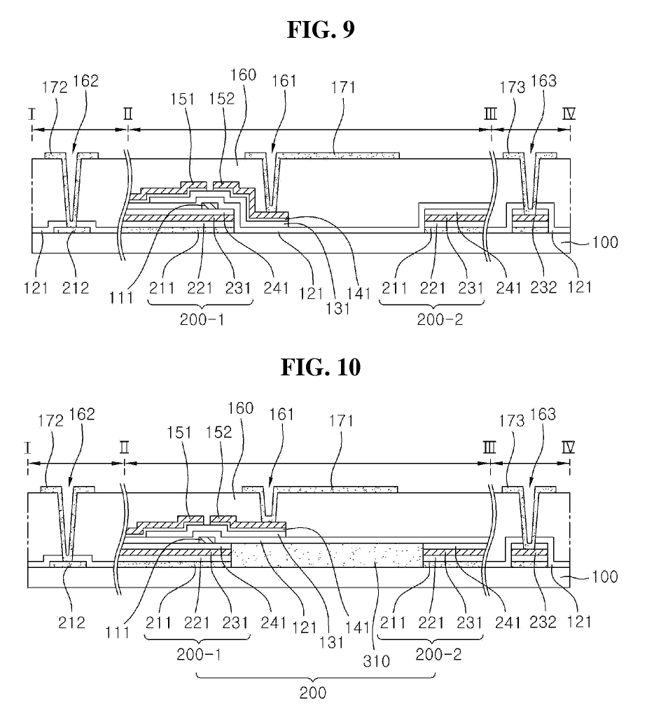

Referring to FIGS. 2 and 9, a passivation layer 160 is formed on an entire structure including the TFT. The passivation layer 160 is then patterned to form a first contact hole 161 exposing a portion of the drain electrode 152. In addition, the passivation layer 160 and the gate insulation layer 121 are patterned to form a second contact hole 162 exposing a portion of the first electrode pad 212. The passivation layer 160, the gate insulation layer 121 and the first insulation layer 241 are patterned to form a third contact hole 163 exposing a portion of the second electrode pad 232.

Thereafter, a transparent conductive layer (not shown) is formed on an entire structure including the first, second and third contact holes 161, 162 and 163, and then patterned to thereby form a pixel electrode 171 connected to the drain electrode 152 exposed through the first contact hole 161, a first electrode auxiliary pad 172 connected to the first electrode pad 212 exposed through the second contact hole 162, and a second electrode auxiliary pad 173 connected to the second electrode pad 232 exposed through the third contact hole 163. Alternative exemplary embodiments include configurations wherein the first and second electrode auxiliary pads 172 and 173 may be omitted. In such an alternative exemplary embodiment, the first and second electrode pads 212 and 232 may be left exposed for connection to external components (not shown). In one exemplary embodiment, the transparent conductive layer may be formed of ITO or IZO.

### Embodiment 2

In another exemplary embodiment of a TFT substrate in accordance with the present invention, a solar cell has a vertical structure to provide a partition with a predetermined height to a light-blocking region that surrounds a display region. Such a partition can function to prevent a liquid color filter from flowing into an adjacent region until the liquid color filter is solidified in exemplary embodiments wherein the color filter is formed through an inkjet method. Herebelow, an array on color filter (“AOC”) type TFT substrate will be described, in which the color filter is formed on a substrate through the inkjet method and the TFT is then formed on the color filter. Duplicate description, which has been made already in the previous exemplary embodiment, will be omitted or described briefly herein.

FIG. 10 is a cross-sectional view of another exemplary embodiment of a TFT substrate in accordance with the present invention, which corresponds to the cross-sectional view taken along lines I-II, II-III and III-IV of FIGS. 1A and 1B.

Referring to FIG. 10, the TFT substrate includes a transparent insulation substrate 100, a gate line GL extending in one direction over the substrate 100, and a data line DL disposed over the substrate 100 and extending in another direction substantially opposite to the gate line GL. Unit pixels PX are defined in intersection regions where the gate lines GL and the data lines cross each other or regions including the intersection regions and areas adjacent thereto. In each of the unit pixels PX, a TFT and a pixel electrode 160 are provided. In addition, each of the unit pixels PX is divided into a light-transmitting region (see A1 of FIG. 1B) and a light-blocking region (see A2 of FIG. 1B). A solar cell pattern 200 is provided in an entire or partial portion of the light-blocking region (see A2 of FIG. 1B).

The solar cell pattern 200 includes at least one of solar cells 200-1 and 200-2. Each of the solar cells 200-1 and 200-2 includes a first electrode 211 on the substrate 100, an active layer 221 on the first electrode 211, and a second electrode 231 on the active layer 221. Similar to the previous exemplary embodiment, the active layer 221 may include a charge transport layer, an n-type layer, a p-type layer and a hole transport layer, which are stacked over the first electrode 211, but the active layer 221 is not limited thereto. In this exemplary embodiment, each of the solar cells 200-1 and 200-2 has a vertically stacked structure with a predetermined height and is continuously formed in the light-blocking region (A2 of FIG. 1B) surrounding the light-transmitting region (A1 of FIG. 1B). Therefore, the solar cell pattern 200 can provide a partition that divides a space into the light-transmitting region A1 and the light-blocking region A2. In the solar cells 200-1 and 200-2 of this exemplary embodiment, because the second electrode 231 is formed of the same material as the gate electrode 111, for example, an opaque conductive material, it can serve as a black matrix which blocks light emitted from the lower side of the solar cell pattern 200.

In an inner space of the partition provided by the solar cell pattern 200, that is, in the light-transmitting region A1, a color filter 310 is provided to give a predetermined color to the light emitted from the lower side and then to emit the light upwardly. Exemplary embodiments include configurations wherein the color filter 310 may be formed to cover either the light-transmitting region A1 or the light-transmitting region A1 and a portion of the light-blocking region A2 adjacent thereto. In one exemplary embodiment, the color filter 310 may be formed such that it can display one of red, green and blue colors for realizing a color image.

An exemplary embodiment of a method for manufacturing the exemplary embodiment of a TFT substrate of FIG. 10 will be described below.

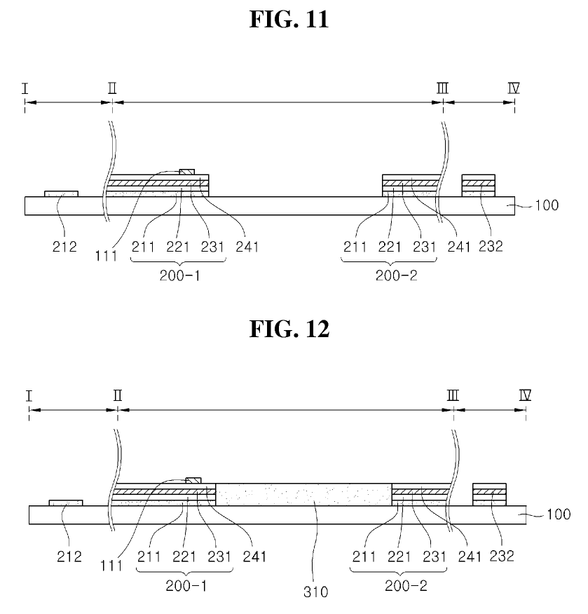

FIGS. 11 through 15 are cross-sectional views illustrating an exemplary embodiment of a method for manufacturing the exemplary embodiment of a TFT substrate of FIG. 10 in accordance with the present invention.

Referring to FIGS. 10 and 11, like the previous exemplary embodiment, a first electrode layer, an active layer layer, a second electrode layer, a first insulation layer and a gate line layer are sequentially formed on a substrate 100, and then patterned to form a solar cell pattern 200, first and second electrode pads 212 and 232 connected to the solar cell pattern 200, and a gate pattern 111 and GL. The solar cell pattern 200 is formed in an entire or partial portion of the light-blocking region A2. The solar cell pattern 200 has a vertically stacked structure with a predetermined height and is continuously formed along the periphery of the light-transmitting region A1. Therefore, the solar cell pattern 200 can provide a partition that divides a space into the light-transmitting region A1 and the light-blocking region A2, e.g., the solar cell pattern 200 is formed to substantially surround the light-transmitting region A1.

Referring to FIGS. 10 and 12, a color filter 310 is formed in the light-transmitting region A1 provided in an inner space of the partition formed by the solar cell pattern 200. In one exemplary embodiment, the color filter 310 may be formed through an inkjet method by spraying a liquid color organic layer on the substrate 100. In such an exemplary embodiment, the solar cell pattern 200 serves as the partition to confine the liquid color organic layer therein, thereby making it possible to prevent the liquid color organic layer from flowing into the periphery and to solidify and fix the color organic layer in position. The color filter 310 may be formed to cover at least the light-transmitting region A1 of each unit pixel. Also, the color filter 310 may be formed such that it can display one of red, green and blue colors for realizing a color image. Although the present exemplary embodiment has been described with respect to an inkjet method of color filter 310 formation, the present invention is not limited thereto.

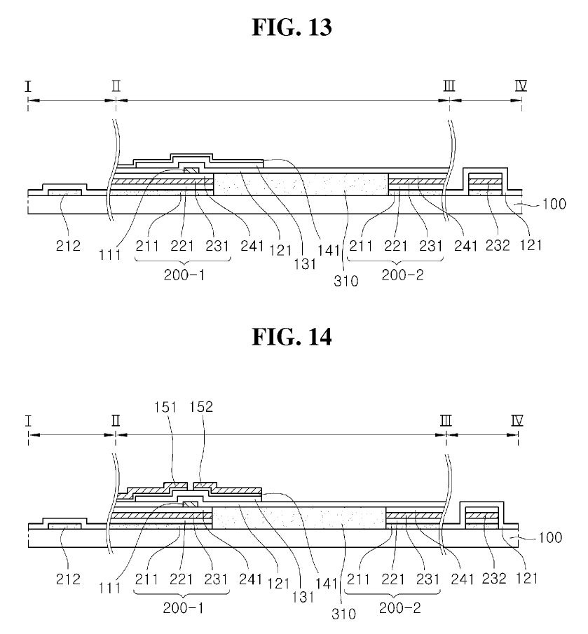

Referring to FIGS. 10 and 13, a gate insulation layer 121 is formed on an entire structure including the gate electrode 111. Thereafter, an active layer 131 and an ohmic contact layer 141 are sequentially formed on the gate insulation layer 121 to form a multi-structured semiconductor layer, and then patterned to form an isolated and island-shaped semiconductor layer over the gate electrode 111. In one exemplary embodiment, the gate insulation layer 121 may be formed of an inorganic insulation material including at least one of silicon oxide (SiO₂) and silicon nitride (SiNx) having excellent adhesive and insulating properties. In one exemplary embodiment, the active layer 131 may be formed of amorphous silicon (“a-Si”). In one exemplary embodiment, the ohmic contact layer 141 may be formed of silicide or n-type heavily doped amorphous silicon (“n+ a-Si”). Furthermore, alternative exemplary embodiments include configurations wherein each unit pixel PX includes a plurality of island-shaped semiconductor layers.

Referring to FIGS. 10 and 14, a data line layer (not shown) is formed on an entire structure including the island-shaped semiconductor layer, and then patterned to form a data pattern including a source electrode 151, a drain electrode 152, a data line (see DL of FIG. 1), and so on. In one exemplary embodiment, the data line layer may be formed of at least one of Al, Mo, Cr, Ti, Ta, Ag and Nd. Afterwards, the ohmic contact layer 141 exposed between the source electrode 151 and the drain electrode 152 is removed so that at least one TFT, which includes the gate electrode 111, the second insulation layer 121, the active layer 131, the ohmic contact layer 131, the source electrode 151 and the drain electrode 152, is provided in each unit pixel PX.

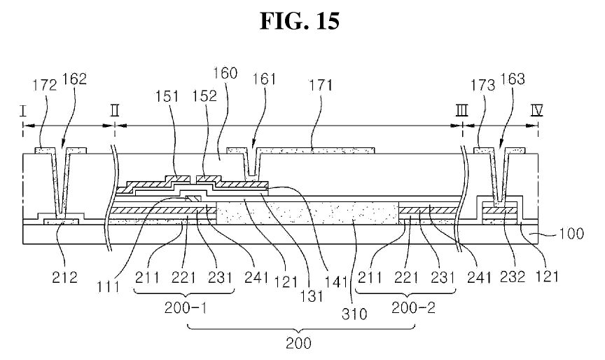

Referring to FIGS. 10 and 15, a passivation layer 160 is formed on an entire structure including the TFT. The passivation layer 160 is then patterned to form a first contact hole 161 exposing a portion of the drain electrode 152. In addition, the passivation layer 160 and the second insulation layer 121 are patterned to form a second contact hole 162 exposing a portion of the first electrode pad 212. The passivation layer 160, the gate insulation layer 121 and the first insulation layer 241 are patterned to form a third contact hole 163 exposing a portion of the second electrode pad 232.

Thereafter, a transparent conductive layer (not shown) is formed on an entire structure including the first, second and third contact holes 161, 162 and 163, and then patterned to thereby form a pixel electrode 171 connected to the drain electrode 152 exposed through the first contact hole 161, a first electrode auxiliary pad 172 connected to the first electrode pad 212 exposed through the second contact hole 162, and a second electrode auxiliary pad 173 connected to the second electrode pad 232 exposed through the third contact hole 163. Alternative exemplary embodiments include configurations wherein the first and second electrode auxiliary pads 172 and 173 may be omitted. In such an alternative exemplary embodiment, the first and second electrode pads 212 and 232 may be left exposed for connection to external components (not shown). The transparent conductive layer may be formed of ITO or IZO.

### Embodiment 3

The previous exemplary embodiments of a TFT substrate in accordance with the present invention may be attached to a common electrode substrate that is separately prepared, thus forming a liquid crystal display (“LCD”) having an LCD panel capable of displaying an image. An exemplary embodiment of an LCD where a solar cell is integrally formed using any one of the previous exemplary embodiments of a TFT substrate of the present invention will be described. Duplicate description, which has been described already in the previous exemplary embodiments, will be omitted or described briefly herein.

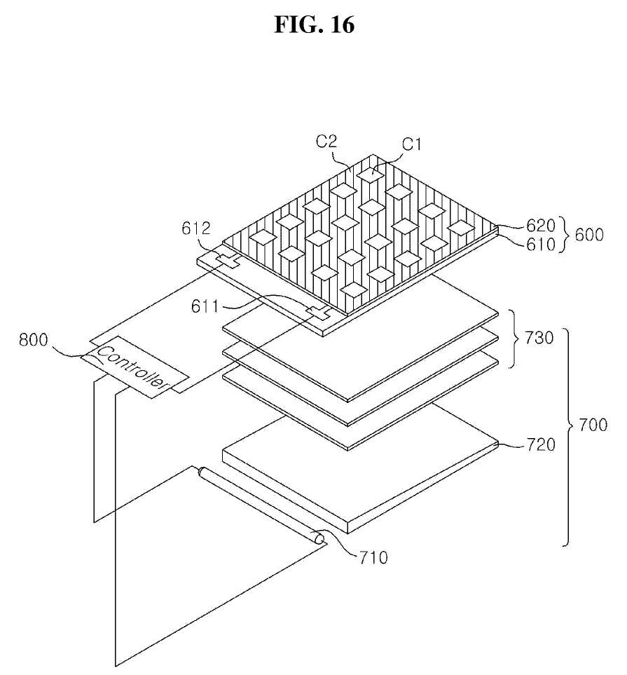

FIG. 16 is a perspective view of an exemplary embodiment of an LCD in accordance with the present invention.

Referring to FIG. 16, the LCD includes an LCD panel 600, a backlight unit 700 disposed under the LCD panel 600, and a controller 800 configured to control the distribution of power generated from a solar cell pattern (not shown). The LCD panel 600 is divided into a light-transmitting region C1 and a light-blocking region C2, wherein individual unit pixels PX are separated from each other by the light-blocking region C2. The solar cell pattern is formed in at least a portion of the light-blocking region C2. Herein, at least one solar cell is provided in the solar cell pattern, and the solar cell is connected to first and second electrode pads 611 and 612 extending outwardly from the light-transmitting region C1 of the LCD panel 600.

The LCD panel 600 includes a lower substrate 610, an upper substrate 620 and a liquid crystal layer (not shown) disposed between the lower and upper substrates 610 and 620. The lower substrate 610 includes a plurality of gate lines, a plurality of data lines crossing the gate lines, a plurality of TFTs formed in regions where the gate lines and the data lines cross each other, and a plurality of pixel electrodes respectively connected to the plurality of TFTs. In the present exemplary embodiment, the upper substrate 620 faces the lower substrate 610, and includes a common electrode and, in one exemplary embodiment, a color filter.

The lower substrate 610 of this exemplary embodiment employs the previously described exemplary embodiments of a TFT substrate in accordance with the present invention wherein a solar cell pattern and first and second electrode pads 611 and 612 connected thereto are formed. The color filter may not be formed on the upper substrate 620 if the color filter is formed on the lower substrate 610, as in the exemplary embodiment of a TFT substrate shown in FIG. 10. This LCD panel 600 controls light transmittance of the liquid crystal molecules of the liquid crystal layer to display a predetermined image according to an externally supplied image signal.

The backlight unit 700 is disposed under the LCD panel 600. The backlight unit 700 of this exemplary embodiment includes a lamp 710 configured to generate light, a light guide plate 720 disposed at one side of the lamp 710 and an optical sheet 730 disposed over the light guide plate 720. Although not shown, the backlight unit 700 may further include a reflection sheet disposed under the light guide plate 720 and other reflective components directing light from the lamp 710 toward the light guide plate 720. The light generated from the lamp 710 is incident on a side surface of the light guide plate 720.

While passing through the light guide plate 720, the light changes its optical distribution such that incoming linear light is converted into planarized surface light, and then emitted toward the optical sheet 730. The optical sheet 730 uniformalize the brightness distribution of the light emitted upwardly from the light guide plate 720, and then provides the light with uniform brightness distribution to the LCD panel 600. The light from the backlight unit 700 which is incident on the light-transmitting region C1 changes light transmittance according to an orientation of the liquid crystal molecules in the liquid crystal layer and is colored while passing through the LCD panel 600. Thereafter, this light is emitted through the front of the LCD panel 600, thereby displaying a color image.

In a related art, light incident on the light-blocking region C2 does not contribute to an image display but is absorbed and lost by the components of the LCD panel 600. In the exemplary embodiments of the present invention, however, the light incident on the light-blocking region C2 is not lost, but is instead converted into electrical energy again to be reused as system power because the solar cell pattern is formed in an entire or partial portion of the light-blocking region C2.

The controller 800 is connected to the first and second electrode pads 611 and 612 provided outside the LCD panel 600 to receive power generated from the solar cell pattern. In addition, in one exemplary embodiment, the controller 800 actively controls the power generated from the solar cell pattern to be suitably distributed according to power supply conditions of a total system. In one such exemplary embodiment, if the power is stably supplied to the total system, the power generated from the solar cell pattern is stored in a charging unit (not shown) which may be separately provided. If, however, the power is not stably supplied, the power stored in the charging unit or the power generated from the solar cell pattern may be distributed as a power for operating the LCD panel 600 or the backlight unit 700. Therefore, it is possible to more effectively manage the power and reduce power consumption as well.

In this way, the solar cell pattern provided in an entire or partial portion of in the light-blocking region C2 can convert light incident onto the light-blocking region C2 in the unit pixel, which does not contribute to an image display, into an electrical energy and reuse this electrical energy. Furthermore, the power generated from the solar cell pattern may be actively managed through the controller, which makes it possible to realize an LCD with low power consumption.

As described above, in accordance with the exemplary embodiments, because a solar cell can be formed in a TFT substrate without an additional mask process by forming a solar cell through a mask process of forming a gate pattern, it is possible to easily manufacture the TFT substrate with the solar cell integrally formed, thus reducing a manufacturing cost of the TFT substrate and the LCD display using the TFT substrate.

Furthermore, in one exemplary embodiment of the present invention, the solar cell may have a predetermined height and thus serve as a partition to divide a space into a light-transmitting region and a light-blocking region, allowing a liquid color filter formed in the light-transmitting region to be confined in an inner space of the partition and preventing the liquid color filter from flowing into an adjacent region. Therefore, the color filter can be formed on the TFT substrate through a liquid inkjet method, and a black matrix can be omitted because layers of the solar cell can serve a role of blocking light.

Moreover, since the solar cell provided in an entire or partial portion of the light-blocking region can convert light incident onto the light-blocking region of the unit pixel, which does not contribute to an image display, into an electrical energy and reuse this electrical energy, it is possible to realize an LCD with low power consumption.

Although the TFT substrate and the method for manufacturing the same have been described with reference to the specific embodiments, they are not limited thereto. Therefore, it will be readily understood by those skilled in the art that various modifications and changes can be made thereto without departing from the spirit and scope of the present invention defined by the appended claims.

What is claimed is:

1. A thin film transistor substrate, comprising:
a substrate including both a light-transmitting region and a light-blocking region;
a solar cell pattern disposed on the light-blocking region of the substrate, and comprising at least one solar cell;
an insulation layer disposed on the solar cell pattern; and
a thin film transistor on the insulation layer.

2. The thin film transistor substrate of claim 1, further comprising a plurality of electrode pads extending from the solar cell pattern to an outer edge of the substrate.

3. The thin film transistor substrate of claim 1, wherein the solar cell comprises:
a first electrode layer disposed on the substrate;
an active layer disposed on the first electrode layer; and
a second electrode layer disposed on the active layer.

4. The thin film transistor substrate of claim 3, wherein the first electrode layer is formed of a transparent conductive material, and the second electrode layer is formed of the same material as a gate electrode of the thin film transistor.

5. The thin film transistor substrate of claim 4, wherein the transparent conductive material comprises one of indium tin oxide and indium zinc oxide.

6. The thin film transistor substrate of claim 4, wherein the gate electrode comprises at least one of aluminum, molybdenum, chromium, titanium, tantalum, silver and neodymium.

7. The thin film transistor substrate of claim 1, wherein the solar cell comprises at least one of a dye-sensitized solar cell, an inorganic semiconductor solar cell and an organic semiconductor solar cell.

8. The thin film transistor substrate of claim 1, wherein the solar cell pattern has a predetermined height and surrounds the light-transmitting region, and
wherein a color filter is provided in the region surrounded by the solar cell pattern.

9. A method for manufacturing a thin film transistor substrate, the method comprising:
preparing a substrate including a light-transmitting region and a light-blocking region;
disposing a first electrode layer, an active layer and a second electrode layer on the substrate in sequence to form a solar cell layer;
disposing an insulation layer on the solar cell layer;
disposing a gate line layer on the insulation layer; and
patterning the gate line layer, the insulation layer and the solar cell layer to form a solar cell pattern in at least a portion of the light-blocking region from the solar cell layer, and to form a gate pattern including a gate electrode and a gate line from the gate line layer.

10. The method of claim 9, wherein the first electrode layer is formed of a transparent conductive material.

11. The method of claim 10, wherein the transparent conductive material comprises one of indium tin oxide and indium zinc oxide.

12. The method of claim 9, wherein the second electrode layer is formed of the same material as the gate line layer.

13. The method of claim 12, wherein the gate line layer comprises at least one of aluminum, molybdenum, chromium, titanium, tantalum, silver and neodymium.

14. The method of claim 9, wherein the patterning of the gate line layer, the insulation layer and the solar cell layer further comprises simultaneously forming a first electrode pad and a second electrode pad from the solar cell layer,
the first electrode pad being connected to the first electrode layer of the solar cell pattern, and the second electrode pad being connected to the second electrode layer of the solar cell pattern.

15. The method of claim 14, wherein the patterning of the gate line layer, the insulation layer and the solar cell layer comprises:
disposing a first photoresist pattern with first, second and third thicknesses on the gate line layer and etching an underlying layer using the first photoresist pattern as an etch mask, to define a first region where a gate pattern, a solar cell pattern and a plurality of electrode pads are to be formed;
forming a second photoresist pattern by removing a portion of the first photoresist pattern substantially equal to the third thickness and etching an underlying layer of the first region using the second photoresist pattern as an etch mask, to remove an overlying layer of the first electrode pad; and
forming a third photoresist pattern by removing a portion of the second photoresist pattern substantially equal to the second thickness and etching an underlying layer of the first region using the third photoresist pattern as an etch mask, to form a gate pattern.

16. The method of claim 15, wherein the first thickness is greater than the second thickness, and the second thickness is greater than the third thickness.

17. The method of claim 9, further comprising, forming a color filter in an inner space surrounded by the solar cell pattern.

18. The method of claim 17, wherein the color filter is formed by an inkjet method.

19. A liquid crystal display comprising:
a thin film transistor substrate, comprising:
a substrate including both a light-transmitting region and a light-blocking region;
a solar cell pattern disposed on the light-blocking region of the substrate, and comprising at least one solar cell;
an insulation layer disposed on the solar cell pattern;
a thin film transistor on the insulation layer; and
a plurality of electrode pads extending from the solar cell pattern to an outer edge of the substrate;
a controller connected to the plurality of electrode pads; and
a lamp connected to the controller,
wherein the controller is configured to provide a power from the electrode pads to the lamp.

20. The liquid crystal display of claim 19, further comprising a charging unit connected to the controller, wherein the controller provides the power from the electrode pads to the charging unit when power is stably supplied to the liquid crystal display and wherein the controller provides the power from the electrode pads to the lamp when power is not stably supplied to the liquid crystal display.
